(19) United States
(12) Patent Application Publication
(10) Pub. No.: US 2008/0157163 A1
(43) Pub. Date: Jul. 3, 2008

(54) EEPROM device and method of forming the same

(75) Inventor: Weon-Ho Park, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/006,421

(22) Filed: Jan. 2, 2008

(30) Foreign Application Priority Data
Jan. 2, 2007 (KR) 10-2007-0000237

(51) Int. Cl. H01L 29/788; H01L 21/336

(52) U.S. Cl. 257/315; 438/257; 257/E29.3; 257/E21.409

(57) ABSTRACT

There are provided EEPROM devices and methods of forming the same. The device includes: a substrate having an active region defined by a device isolation layer; a first sense line and a second sense line which straightly extend on the substrate and have a memory gate; a first word line and a second word line which extend to be parallel to the first sense line and the, second sense line at the substrate and have a select gate; and an isolation region which extends in a direction crossing an extension direction of the first sense line and the second sense line to parts of the first and second word lines, which discontinuously electrically isolates the memory gates, and which makes the select gate stepped.

### CROSS REFERENCE TO RELATED APPLICATIONS

This U.S. non-provisional patent application claims priority under 35 U.S.C. §119 to Korean Patent Application No. 10-2007-0000237 filed on Jan. 2, 2007, the entire contents of which are incorporated herein by reference.

### BACKGROUND OF THE INVENTION

1. Field of the Invention

The present invention relates to non-volatile memory devices and methods for forming the same. More particularly, the present invention relates to EEPROM devices and methods for forming the same.

2. Description of the Related Art

An EEPROM (Electrically Erasable Programmable Read Only Memory) device can be electrically programmable and erasable. The EEPROM device is one type of non-volatile memory device, which does not lose stored data although a power supply is cut off. Especially, in an EEPROM device of a FLOTOX (Floating gate tunnel oxide) type, two transistors, such as a select transistor and a memory transistor compose one cell. The memory transistor comprises a floating gate. Data are stored in the floating gate by injecting/emitting electrons into/from the floating gate by a Fowler-Nordheim tunneling effect. The FLOTOX-type EEPROM device is adopted on a smart card, for example, and used for storing user and business information.

FIG. 1A is a plan view showing a conventional EEPROM device. Referring to FIG. 1A, a conventional EEPROM device 10 includes active regions 13 and device isolation layers 12 formed on a substrate 11. Word lines 40 and sense lines 60 are arranged to cross over the active region 13 of the substrate 11 in a Y direction. The sense lines 60 are arranged at right/left sides of a common source 14 extending in the Y direction at the substrate. Tunnel oxide layers 15 are arranged underneath the sense lines 60. A bit line contact 16 is formed at a side of the word line 40 at the active region 13. A floating gate isolation region 17 extends over the device isolation layer 12 of the substrate 11 in an X direction for floating gate isolation. The floating gate isolation region 17 means a region where a conductive layer comprising a floating gate is not formed when an EEPROM device is formed.

FIG. 1B is a cross-sectional view taken along I-I line of FIG. 1A. Referring to FIG. 1B, a gate oxide layer 18 is formed on the substrate 11. A word line 40 and a sense line 60 are formed over the gate oxide layer 18, for example, by a self-aligned etching process. The sense line 60 includes a memory gate 50 having a floating gate 31, a control gate 33. and a gate interlayer dielectric layer 32 interposed therebetween. Data are stored into the floating gate 31. A tunnel oxide layer 15 is formed underneath the floating gate 31 of the sense line 60. The tunnel oxide layer 15 is thinner than the gate oxide layer 18. The word line 40 includes a select gate 30 having a floating gate 31, a control gate 33, and a gate interlayer dielectric layer 32 interposed therebetween. The floating gate 31 and the control gate 33 are electrically connected to each other at a predetermined region. Junctions 14, 19 and 20 are formed on the substrate 11.

FIG. 1C is a cross-sectional view taken along II-II line of FIG. 1A. FIG. 1D is a cross-sectional view taken along III-III line of Fig. 1A. Referring to FIGS. 1C and 1D, the floating gate 31 of the sense line 60 is removed from the device isolation layer 120. That is, the floating gate 31 of the sense line 60 is isolated by the floating gate isolation region 17.

Referring back to FIG. 1A, in the conventional EEPROM device 10, the sense line 60 has an irregular shape for isolating the floating gate (reference number 31 of FIG. 1C) composing the sense line 60. Hence, a width W₂ of the sense line 60 (see FIG. 1 C), which is located at the floating gate isolation region 17, is narrower than a width W₁ of the sense line 60 (see FIG. 1B), which is formed over the active region 13. Because of the shape of sense line 60, an area of the gate interlayer dielectric layer 32 where the sense line 60 and the floating gate isolation region 17 overlap (see FIG. 1C) is decreased.

The shrinkage in area of the gate interlayer dielectric layer 32 leads to decrease of coupling ratio to decrease program/erase effect of the EEPROM device 10. The problem such as decrease of the coupling ratio can be aggravated, as dimensions of EEPROM devices are scaled down. Furthermore, a misalignment between the floating gate isolation region 17 and the sense line 60 can occur, as dimensions of EEPROM devices are scaled down. In the conventional EEPROM device 10, there are many misalignment weak points 80 and program/erase effect-lowering points 90.

### SUMMARY OF THE INVENTION

In accordance with aspect of the present invention provided are EEPROM devices and methods of forming the same, which can improve program/erase effect without increasing of cell size.

In accordance with aspects of the present invention, also provided are EEPROM devices and methods of forming the same, which can improve misalignment processes margin without an increase of cell size.

In accordance with aspects of the present invention, provided are EEPROM devices and methods of forming the same. In the EEPROM devices and the methods, a sense line is formed to have a straight form, thereby improving program/erase effects. Furthermore, a floating gate isolation region connects two neighboring cells facing a common source and extends to a part of a word line, thereby improving misalignment process margin.

In accordance with one aspect of the present invention, provided is an EEPROM device comprising: a substrate having a first junction extending in a first direction; word lines extending in the first direction, the word lines being arranged at both sides of the first junction, and having a select gate comprising a first floating gate, a first control gate, and a first gate interlayer dielectric layer interposed between the first floating gate and the first control gate, wherein the first gate interlayer dielectric layer and the first control gate have stepped shapes; and a sense lines extending in the first direction, the sense lines being arranged between the first junction and the word lines, and each sense line having a memory gate comprising a second floating gate, a second control gate, and a second gate interlayer dielectric layer interposed between the second floating gate and the second control gate, wherein the second floating gate is discontinuous in the first direction.

In the EEPROM device, the first floating gate and the second floating gate can include identical first conductive layers, the first gate interlayer dielectric layer and the second gate interlayer dielectric layer can include identical insulators, and the first control gate and the second control gate can include identical second conductive layers.

The EEPROM device can further include a second junction having a first doped region and a second doped region under the sense line. One of the first doped region and the second doped region can include an impurity concentration that is higher than the other.

The EEPROM device can further include a tunnel oxide layer contacting the second junction and defining a path configured to enable an electron to be tunneled into and from the second floating gate.

The EEPROM device can further include a bit-line contact and a third junction electrically connected to the bit-line contact on the substrate at a side of the word line.

In the EEPROM device, the first gate interlayer dielectric layer can cover upper and side surfaces of the first floating gate and have a stair-type structure, and the first control gate can cover upper and side surfaces of the first gate interlayer dielectric layer to form a square-type structure.

In accordance with another aspect of the present invention, provided is an EEPROM device including: a substrate having a common source extending in a first direction; sense lines. extending in the first direction on the substrate, the sense lines being arranged at both sides of the common source, and each having a floating gate, a first gate interlayer dielectric layer, and a first control gate sequentially stacked; word lines extending in the first direction on the substrate and having a second floating gate, a second gate interlayer dielectric layer, and a second control gate sequentially stacked; and a floating gate isolation region extending from the common source in a second direction crossed over the first direction, the floating gate isolation region being defined as a part where an entire part of the first floating gate and a part of the second floating gate are removed to discontinuously electrically isolate the first floating gate, and to make the second gate interlayer dielectric layer and the second control gate step-shaped.

In the EEPROM device, the second gate interlayer dielectric layer can have a stair-type shape and the second control gate can have a square-type shape.

The EEPROM device can further include a tunnel oxide layer and a floating doped region which are electrically connected to the first floating gate under the sense line.

The EEPROM device can further include a drain electrically connected to a bit line contact at the substrate at a side of the word line.

In accordance with anther aspect of the present invention, provided is an EEPROM device including: a substrate having a device isolation region and an active region; a straight first sense line and a straight second sense line formed on the substrate and each having a memory gate; a first word line and a second word line extending to be parallel to the first sense line and the second sense line on the substrate and each having a select gate; and an isolation region extending to parts of the first word line and the second word line in a direction crossing the first sense line and the second sense line to discontinuously electrically isolating the memory gate and make the select gate having a stepped shape.

In the EEPROM device, the isolation region can be defined as a region where a conductor comprising the memory gate and the select gate is partially removed over the device isolation layer.

The EEPROM device can further include a common source at the active region between the first sense line and the second sense line, and the isolation region crosses over the common source.

In the EEPROM device, the isolation region can be located over the device isolation layer.

The EEPROM device can further include: a floating doped region having a high concentration impurity doped region and a low concentration impurity doped region at the active region under the memory gate; and a tunnel oxide layer providing a tunneling path for electrons between the floating doped region and the memory gate.

The EEPROM device can further include a bit line contact at the active region of the substrate and a drain electrically connected to the bit line contact at the active region under a side of the select gate.

In accordance with another aspect of the present invention, provided is a method of forming an EEPROM device, including: preparing a substrate comprising a sense line region and a word line region; forming a gate oxide layer on the substrate; forming a tunnel oxide layer at the sense line region; forming a first conductive layer on the substrate, the first conductive layer crossing over the sense line region to extend to a part of the word line region and defining a floating gate isolation region; forming an insulation layer and a second conductive layer on the substrate; patterning the second conductive layer, the insulation layer, and the first conductive layer to form a sense line at the sense line region having a floating gate electrically isolated by the floating gate isolation region and to form a word line at the word line region, wherein the sense line formed at the floating gate isolation region has a structure where the insulation layer and the second conductive layer are evenly stacked on the substrate, and wherein the word line formed at the floating gate isolation region has a structure where the insulation layer and the second conductive layer are unevenly stacked over the first conductive layer; and forming a first junction, a second junction and a third junction on the substrate.

In the method, the forming of the first conductive layer defining the floating gate isolation region can include: forming a conductor on the substrate; and patterning the conductor to remove the conductor formed at the sense line region and a part of the conductor formed at the word line region.

In the method, the substrate can include an active region between the sense lines regions, and the floating gate isolation region can cross over the active region.

In the method, the forming of a first junction, a second junction, and a third junction can include: forming the first junction on the substrate between the sense lines; forming the second junction comprising a first impurity doped region and a second impurity doped region; and forming the third junction on the substrate under a side of the word line. The forming of the second junction can include forming the first impurity doped region on the substrate under the sense line, and forming the second impurity doped region connected to the first impurity doped region on the substrate between the sense line and the word line.

In the method, the forming of the first impurity doped region can be performed in a step of forming the tunnel oxide layer, and the forming of the second impurity doped region can be performed in a step of forming the first junction, the second junction, and the third junction.

In the method, the first impurity doped region can be formed to have impurity concentration higher than the second impurity doped region.

In the method, the forming of the structure where the insulation layer and the second conductive layer are unevenly stacked on the first conductive layer can include: forming an insulation layer on upper and side surfaces of the first conductive layer to be stair-type shaped at the word line region; and forming the second conductive layer to be square-type shaped on the insulation layer.

In the method, the sense line can be formed to be straight shaped in a direction orthogonal to an extension direction of the floating gate isolation region.

In accordance with another aspect of the present invention, provided is a method of forming an EEPROM device, including: providing a substrate having a sense line region and a word line region; forming a gate oxide layer on the substrate; forming a tunnel oxide layer having a thinner thickness than the gate oxide layer; forming a first impurity doped region under the tunnel oxide layer on the sense line region; forming a first conductive layer on the substrate; patterning the first conductive layer to form a first conductive pattern exposing an entire part of the substrate of the sense line region but exposing a part of the substrate of the word line region; forming an insulation layer and a second conductive layer on the substrate; patterning the second conductive layer, the insulation layer, and the first conductive pattern to form a sense line and a word line straightly extending in one direction at the sense line region where an entire surface of the substrate is exposed and a word line a the word line region where a part of the substrate is exposed, wherein the sense line comprises the insulation layer and the second conductive layer sequentially stacked, and wherein the word line comprises the first conductive layer, the insulation layer covering upper and side surfaces of the first conductive layer and having a stair-type shape, and the second conductive layer being positioned on the insulation layer and having a square-type shape; forming a common source on the substrate between the sense lines; forming a second impurity doped region connected to the first impurity doped region on the substrate between the sense line and the word line to constitute a floating junction comprising the first and second impurity doped regions, and forming a drain on the substrate under the word line.

In the method, the first impurity doped region can be formed to have impurity concentration higher than the second impurity doped region.

In the method, the sense line can straightly extend in one direction on the substrate.

In accordance with another aspect of the present invention, provided is a method of forming an EEPROM device, including: preparing a substrate having an active region and a device isolation region; forming a sense line extending in a first direction and crossing over the active region on the substrate; forming a word line extending parallel to the sense line and crossing over the active region on the substrate; and forming an isolation region crossing over the sense line and extending to a part of the word line in a second direction orthogonal to the first direction for isolating a floating gate of the sense line on the substrate.

In the method, the forming of the isolation region can include: forming a conductive layer on the substrate; and patterning the conductive layer to expose an entire part where the sense line is formed and a part were the word line is formed on the substrate.

In the method, the EEPROM device can further include a common source at the active region between the sense lines and the isolation region can cross over the common source.

According to aspects of the present invention, an isolation region for isolating a floating gate extends to both left and right sides of a common source and to a part of a word line. Therefore, it is possible to improve a misalignment process margin between an isolation region and a sense line. Furthermore, sense line can be formed to be a straight form, thereby enlarging an area of a gate interlayer dielectric layer of a memory gate and improving program/erase effects.

### BRIEF DESCRIPTION OF THE DRAWINGS

The present invention will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the invention. In the drawings:

FIG. 1A is a plan view illustrating a conventional EEPROM device.

FIG. 1B is a cross-sectional view taken by cutting FIG. 1A along I-I line.

FIG. 1C is a cross-sectional view taken by cutting FIG. 1A along II-II line.

FIG. 1D is a cross-sectional view taken by cutting FIG. 1A along III-III line.

FIG. 2A is a plan view illustrating an embodiment of an EEPROM device according to the aspects of present invention.

FIG. 2B is a cross-sectional view taken by cutting FIG. 2A along I-I line.

FIG. 2C is a cross-sectional view taken by cutting FIG. 2A along II-II line.

FIG. 2D is a cross-sectional view taken by cutting FIG. 2A along III-III line.

FIGS. 3A through 3F are sectional views illustrating an embodiment of a method of forming an EEPROM device of FIG. 2B according to aspects of the present invention.

FIGS. 4A, 4B, 4C, 4D, 4E and 4F are sectional views illustrating an embodiment of a method of forming an EEPROM device of FIG. 2C according to aspects of the present invention.

FIGS. 5A through 5F are sectional views illustrating an embodiment of a method of forming an EEPROM device of FIG. 2D according to the present invention.

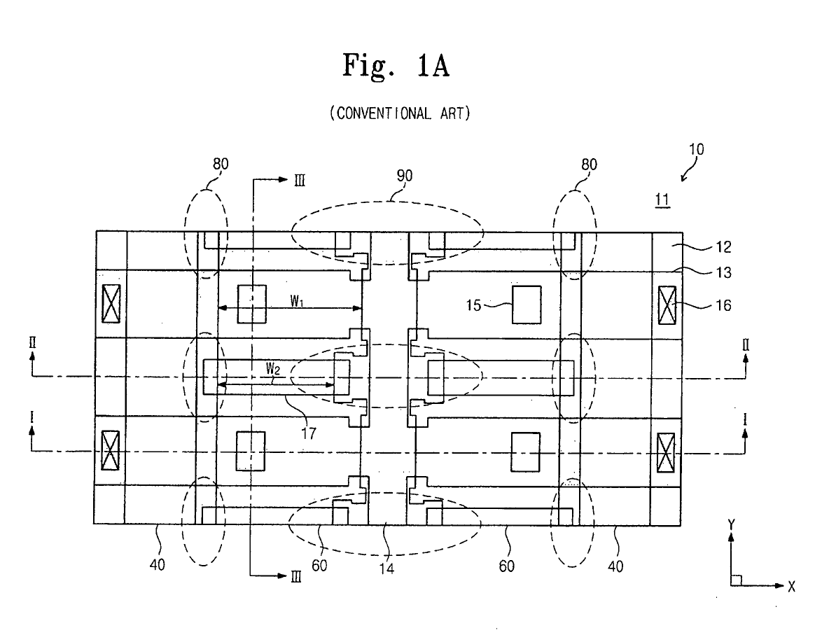

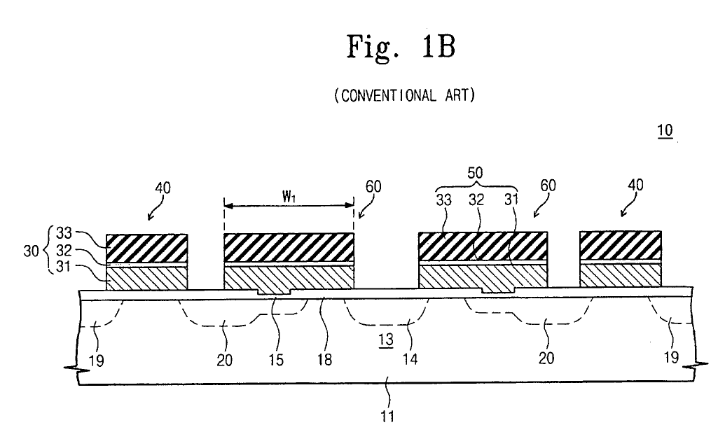

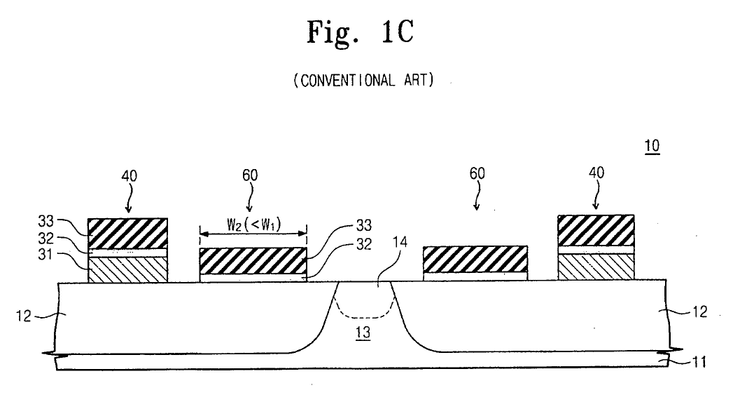

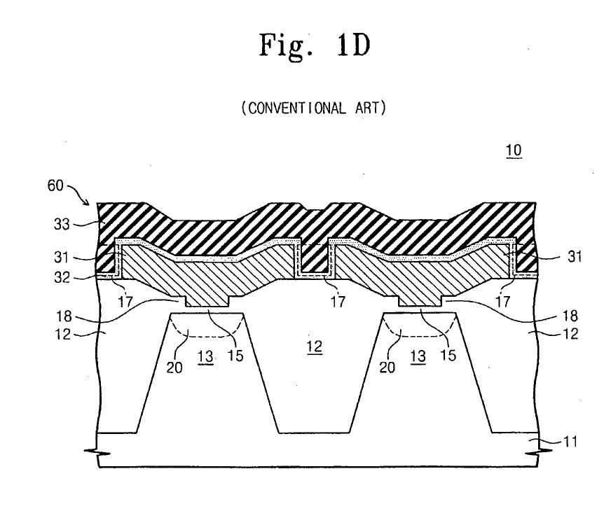

### DETAILED DESCRIPTION OF THE INVENTION

Aspects of the present invention will now be described more fully hereinafter with reference to the accompanying drawings, in which preferred embodiments are shown. This invention can, however, be embodied in many different forms and should not be construed as limited to the embodiments set forth herein.

In the drawings, the thickness of layers and regions are exaggerated for clarity. It will be understood that when an element such as a layer, region or substrate is referred to as being “on” another element, it can be directly on the other element or intervening elements can also be present.

Furthermore, relative terms, such as “beneath”, can be used herein to describe one element's relationship to another elements as illustrated in the Figures. It will be understood that relative terms are intended to encompass different orientations of the device in addition to the orientation depicted in the Figures. For example, if the device in the Figures is turned over, elements described as “below” other elements would then be oriented “above” the other elements. The exemplary term “below”, can therefore, encompasses both an orientation of above and below.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second without departing from the teachings of the present invention. Like numbers refer to like elements throughout.

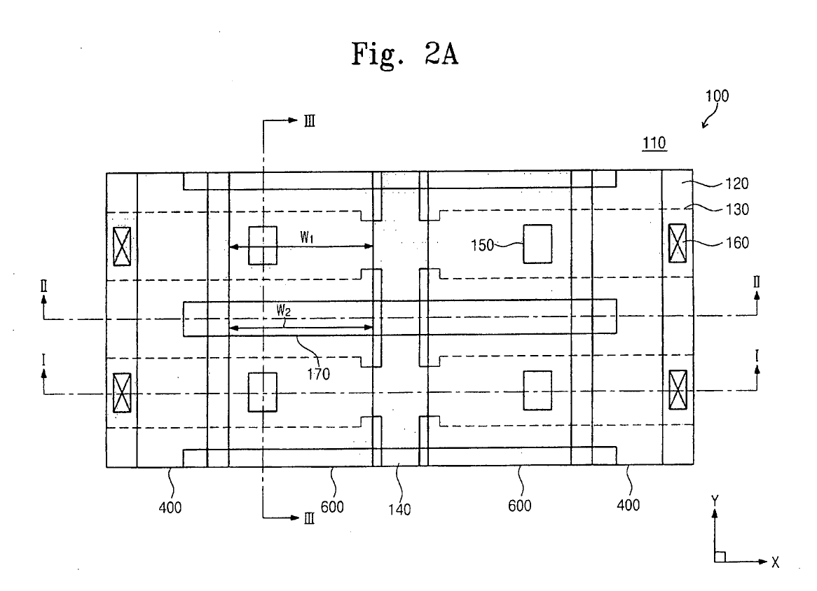

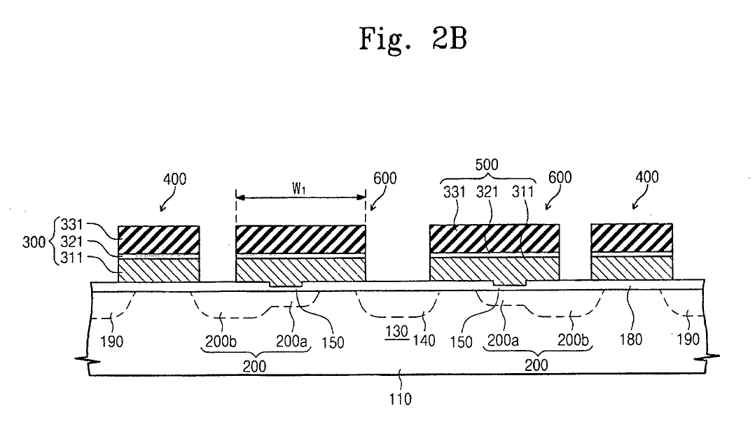

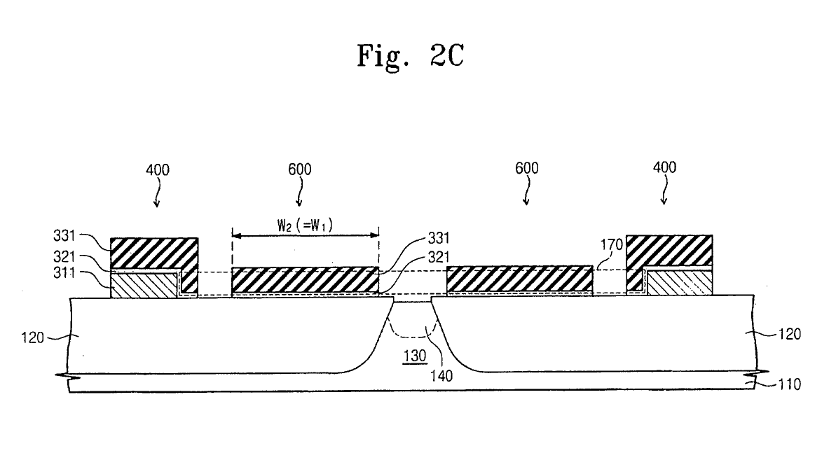

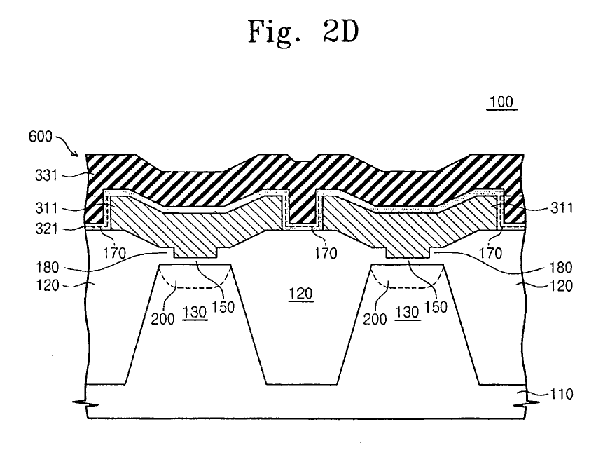

FIG. 2A is a plan view illustrating an embodiment of an EEPROM device according to aspects of the present invention.

Referring to FIG. 2A, an EEPROM device 100 of the present embodiment includes a substrate 110 having an active region 130 and a device isolation layer 120. The device 100 includes a word line 400 and a sense line 600 extending to be parallel to each other in a Y direction over the substrate 110. The active region 130 is defined by the device isolation layer 120 and extends in X and Y directions. The X direction can be substantially orthogonal to the Y direction. A first junction 140, which can be referred to as a common source, is formed at the active region 130 extending to the Y direction at the substrate. A bit line contact 160 is formed at a side of the word line 400 at the active region 130 extending to the X direction. The sense lines 600 are nearer to the first junction 140 than the word line 400 and arranged at both left and right sides of the first junction 140. A tunnel oxide layer 150 where Fowler-Nordheim (FN) tunneling occurs is formed on the active region 130 under the sense line 600.

A floating gate isolation region 170 extends to the X direction for a floating gate isolation over the device isolation layer 120. The floating gate isolation region 170 can be defined as a region without a conductive layer composing a floating gate. A floating gate composing the sense line 600 is electrically isolated by the floating gate isolation region 170. The floating gate isolation region 170 extends not only to the sense lines 600 at both sides of the first junction 140 but also to a part of the word line 400. The floating gate isolation region 170 crosses over the first junction 140. Consequently, there is no need for forming a sense line 600 in an irregular manner to electrically isolate the floating gate, as is conventional. The sense line 600 can be formed to be a straight form in the Y direction, so that a first width W₁ (see FIG. 2B) at the active region 130 is identical to a second width W₂ (see FIG. 2C) at the floating gate isolation region 170.

FIG. 2B is a cross-sectional view taken by cutting FIG. 2A along I-I line.

Referring to FIG. 2B, a gate oxide layer 180 is formed on the substrate 110, and the word line 400 and the sense line 600 are arranged over the gate oxide layer 180. The sense line 600 includes a memory gate 500 including a floating gate 311, a control gate 331, and a gate interlayer dielectric layer 321 interposed therebetween. Data are stored into the floating gate 311. The sense line 600 has a first width W₁. The tunnel oxide layer 150, which is thinner than the gate oxide layer 180, is formed under the floating gate 311 of the sense line 600. The word line 400 includes a select gate 300 including a floating gate 311, a control gate 331 and a gate interlayer dielectric layer 321 interposed therebetween. The floating gate 311 of the word line 400 is electrically connected to the control gate 331 at a predetermined region. The substrate 110 can be a silicon wafer. The floating gate 311 and the control gate 331 can be a conductor, such as a polysilicon and a metal, and the gate interlayer dielectric layer 321 can be an oxide-nitride-oxide (ONO) layer.

A plurality of junctions 140, 190 and 200 are formed at the active region 130. A first junction 140 is formed between the sense lines 600 to be a common source. A second junction 200 is formed under the tunnel oxide layer 150 to be a floating junction where the FN tunneling can occur. A third junction 190 is formed at a side of the word line 400, as a drain electrically connected to a bit line contact (a reference number 160 in FIG. 2A). If the substrate 110 is a first conductive type, for example, a P type silicon wafer, the first and third junctions 140 and 190 can be a second conductive_type, for example, N⁺-type impurity region of high concentration, and the second junction 200 can be a second conductive type, for example, having a N⁻-type doped region 200a of a low concentration and a N⁺-type doped region 200b of high voltage high concentration.

FIG. 2C is a cross-sectional view taken by cutting FIG. 2A along II-II line.

Referring to FIG. 2C, the first junction 140, which can be named as a common source, is formed at the active region 130 of the substrate 110. Word lines 400 and sense lines 600 are formed over the device isolation layer 120 at both left and right sides of the first junction 140. The floating gate isolation region 170 crosses over the first junction 140 and extends to both left and right sides of the first junction 140. A center of the floating gate isolation region 170 is located over the first junction 140. The floating gate 311 is removed in the floating gate isolation region 170. Consequently, the sense line 600 located over the floating gate isolation region 170 does not have the floating gate 311, but has a form in which the control gate 331 is stacked on the gate interlayer dielectric layer 321. Furthermore, the floating gate isolation region 170 extends to a part of the word line 400, so that a part of the floating gate 311 is removed from the word line 400. The gate interlayer dielectric layer 321 of the word line 400 has a stair-shaped structure, and the control gate 331 has a square-shaped structure such as “ [symbol] ” and “ [symbol] ” The sense line 600 has a straight form, so that a width of the sense line 600 is constant through a whole length of the sense line 600. That is, a first width W₁ of the sense line 600 located over the active region 130 in FIG. 2B is substantially equal to a second width W₂ of the sense line 600 located over the floating gate isolation region 170.

FIG. 2D is a cross-sectional view taken by cutting FIG. 2A along III-III line.

Referring to FIG. 2D, the sense line 600 is formed on the substrate 110 having the active region 130. The sense line 600 includes the tunnel oxide layer 150, the floating gate 311 contacting the tunnel oxide layer 150, the control gate 331 being stacked on the floating gate 311 to control the floating gate 311, and the gate interlayer dielectric layer 321 interposed between the floating gate 311 and the control gate 331. Data are stored in the floating gate 311. A second junction 200 is located in the active region 130 under the tunnel oxide layer 150. The floating gate 311 is isolated by the floating gate isolation region 170.

Referring to FIGS. 2A through 2D, the floating gate isolation region 170 extends to both left and right sides of the first junction 140 and, in this embodiment, has its center at the first junction 140, so that there is no need to form the sense line 600 in an irregular fashion to electrically isolate the floating gate 311, as there is in conventional devices. The sense line 600 can be straight and formed in the Y direction, thereby having a constant width (W₂=W₁).

Program/erase/read operations of the EEPROM device 100 can be performed as follows. In order to erase the EEPROM device 100, high bias, for example, 15˜20 volts, is applied on both the sense line 600 and the word line 400, 0 volts are applied on the third junction 190, and the first junction 140 is floated or 0 volts are applied on the first junction 140. Then, electrons are injected into the floating gate 311 of the sense line 600 by Fowler-Nordheim tunneling, and a threshold voltage of the sense line 600 increases to accomplish the erase operation.

In order to program the EEPROM device 100, 0 volts are applied on the sense line 600, high bias, such as 15˜20 volts, is applied on the word line 400, and the first junction 140 is floated. Then, electrons trapped in the floating gate 311 are emitted out and the threshold voltage of the sense line 600 is lowered to −4˜0 volts to realize the program operation.

In order to read data programmed in the sen se line 600, voltages are applied on both the third junction 200 and the sense line 600 to check out the existence of current flow in the sense line 600.

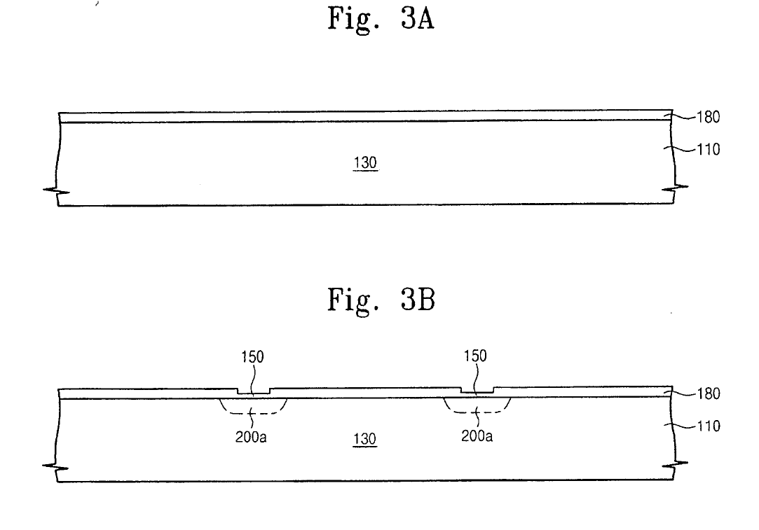

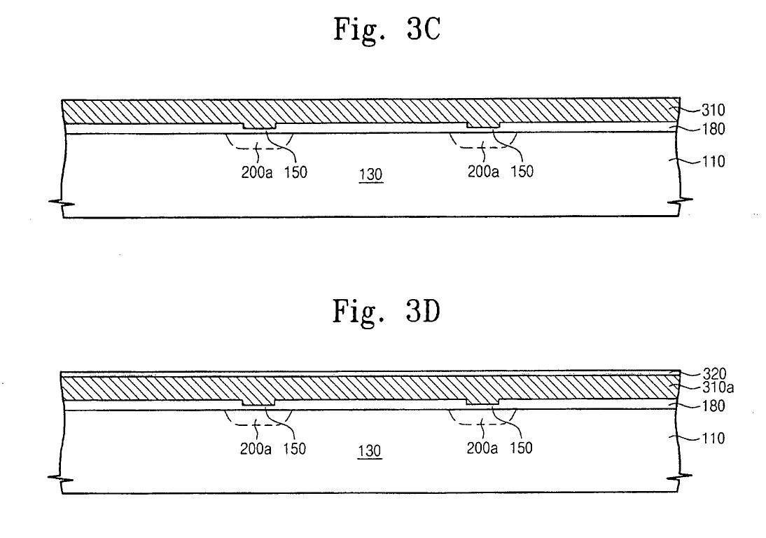

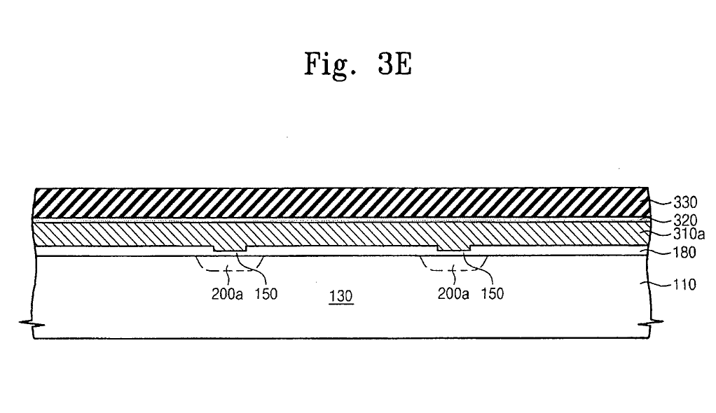

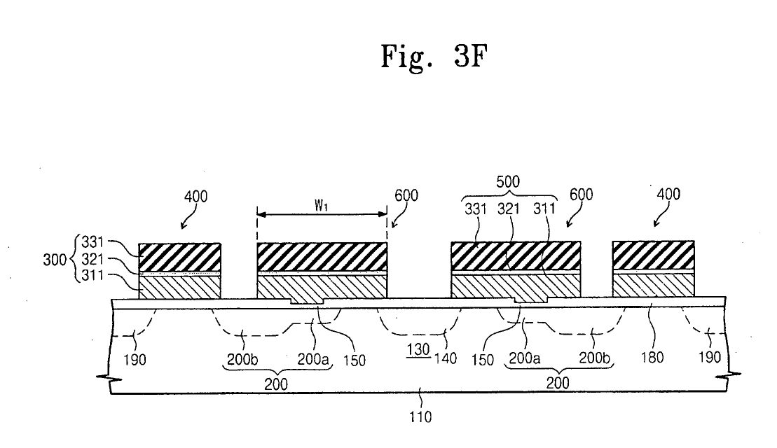

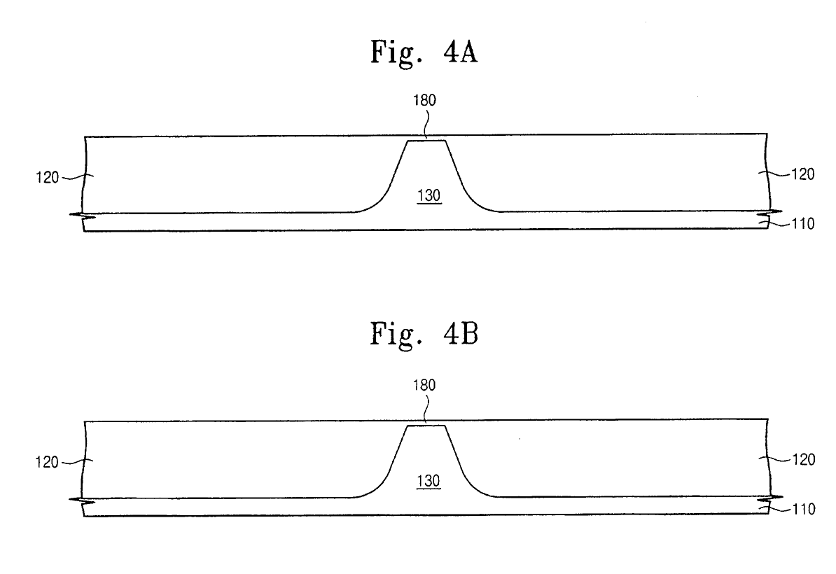

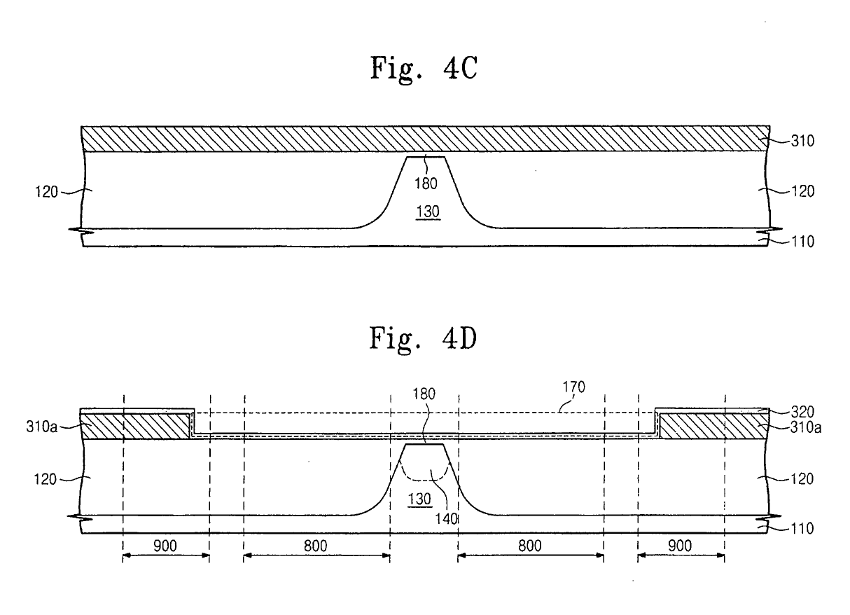

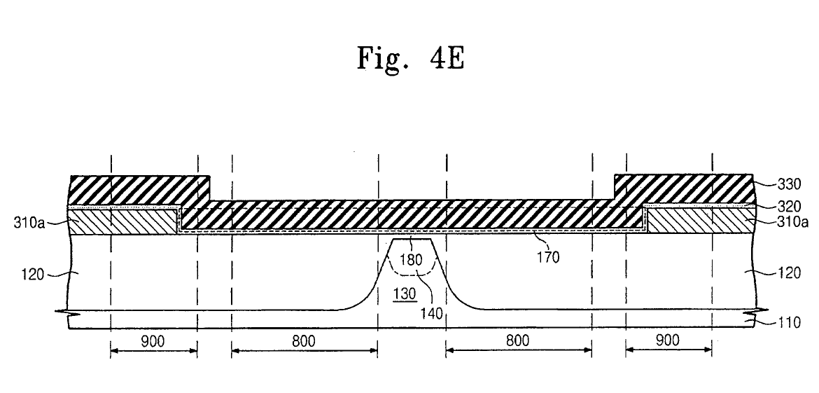

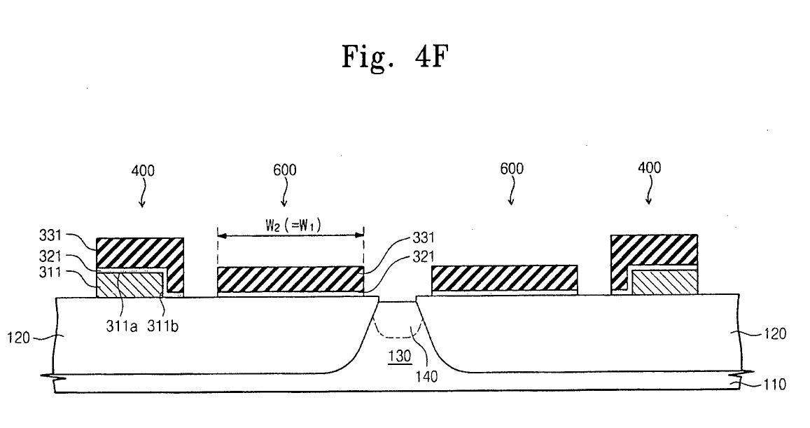

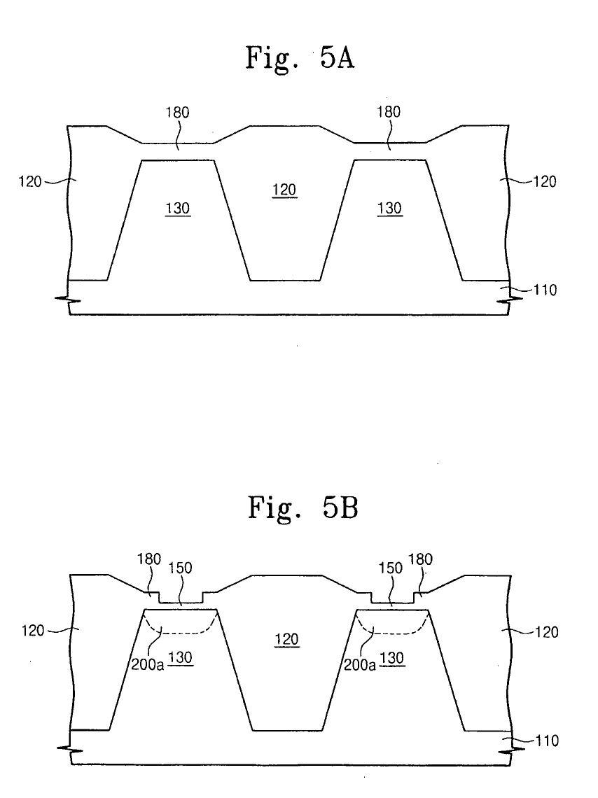

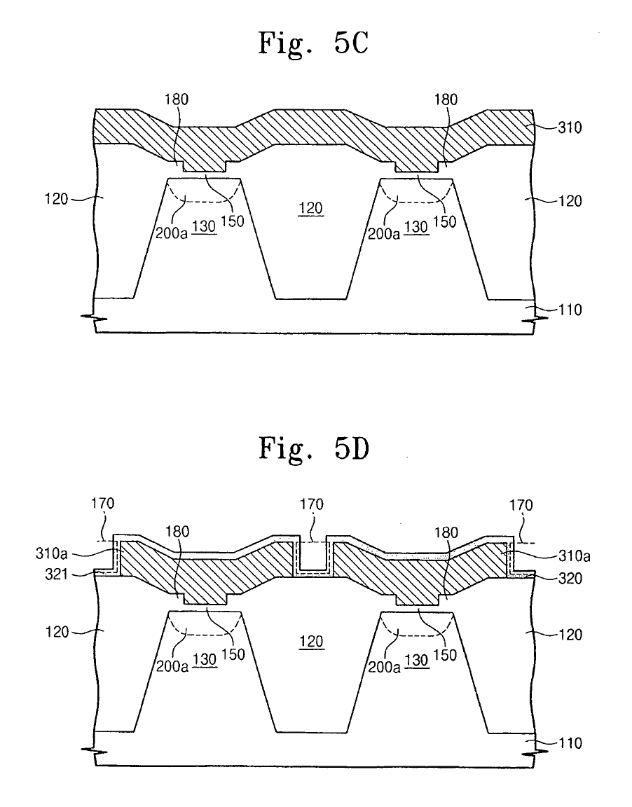

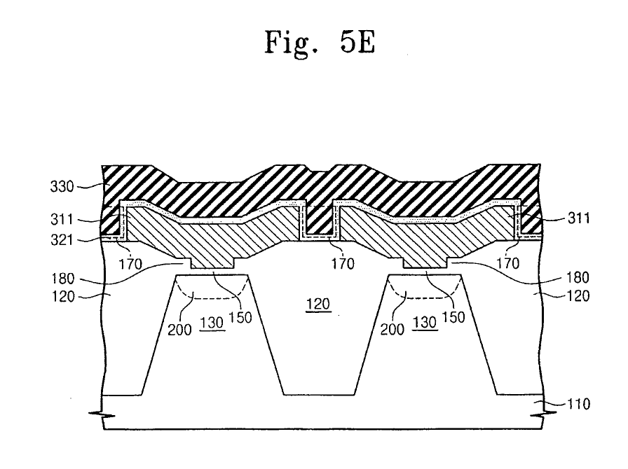

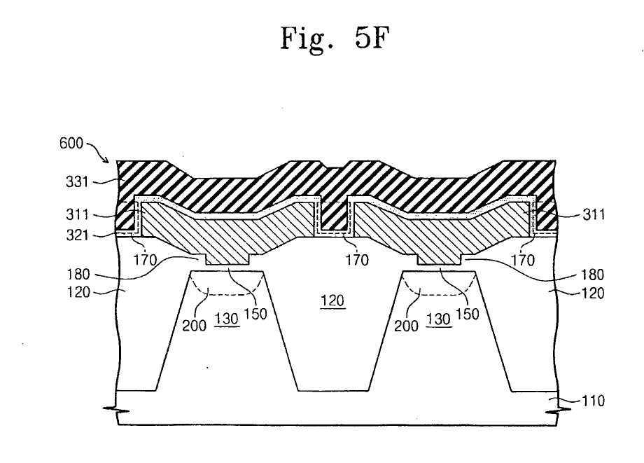

FIGS. 3A through 3F are sectional views illustrating an embodiment of a method of forming an EEPROM device of FIG. 2B according to aspects of the present invention. FIGS. 4A through 4F are sectional views illustrating an embodiment of a method of forming an EEPROM device of FIG. 2C according to aspects of the present invention. And FIGS. 5A through 5F are sectional views illustrating an embodiment of a method of forming an EEPROM device of FIG. 2D according to aspects of the present invention.

Referring to FIGS. 3A, 4A and 5A, the substrate 110 is prepared. The gate oxide layer 180 is formed on the substrate 110. For example, the substrate 110 can be a P-type silicon wafer. The device isolation layer 120 is formed to define active region 130 at the substrate 110. The gate oxide layer 180 can be formed by a thermal oxidation process, for example.

Referring to FIGS. 3B, 4B and 5B, the tunnel oxide layer 150 is formed to be thinner than the gate oxide layer 180. The tunnel oxide layer 150 is a dielectric layer where Fowler-Nordheim tunneling can occur in the case of program/erase operations. For example, in order to form the tunnel oxide layer 150, a part of the gate oxide layer 180 is removed and then a thermal oxidation process can be performed. A high-concentration N⁺-type doped region 200a, which can be a second conductive type, is formed at the active region 130 under the tunnel oxide layer 150. A photolithography process and ion-implantation process can be performed to form the high-concentration N⁺-type doped region 200a, and then, a thermal oxidation process can be performed to form the tunnel oxide layer 150. Alternatively, a photolithography process and ion-implantation process can be performed to form the high-concentration N⁺-type doped region 200a, and then, a photolithography process and an etching process can be performed to form the tunnel oxide layer 150.

Referring to FIGS. 3C, 4C and 5C, a first conductive layer 310 is formed on the gate oxide layer 180. The first conductive layer 310 comprises a floating gate, and for example, can be formed by depositing a polysilicon using a chemical vapor deposition method. A part of the first conductive layer 310 can be electrically connected to the high-concentration N⁺-type doped region 200a via the tunnel oxide layer 150.

Referring to FIGS. 3D, 4D and 5D, a first conductive pattern 310a is formed by a photolithography process and an etching process. When the first conductive pattern 310a is formed, a floating gate isolation region 170 is defined for floating gate isolation (see, for example, FIG. 4D). Then, an insulation layer 320 is formed at an entire surface of the substrate 110 having the first conductive pattern 310a. The insulation layer 320 can be formed of an oxide-nitride-oxide (ONO) layer.

The floating gate isolation region 170 extends to a sense line region 800 (see FIG. 4E) at both left and right sides of the active region 130 by centering the active region 130. The floating gate isolation region 170 also extends to a part of a word line region 900. The sense line region 800 is a region where a sense line (a reference number 900 of FIG. 4F) is formed in a subsequent process, and the word line region 900 is a region where a word line (a reference number 400 of FIG. 4F) is formed in a subsequent process. Since the floating gate isolation region 170 extends to a part of the word line region 900, the first conductive pattern 310a is formed at a part of the word line region 900.

Subsequently, an insulation layer 320 is formed at an entire surface of the substrate 110 having the first conductive pattern 310a. The insulation layer 320 can be formed of an ONO layer in which oxide-nitride-oxide are sequentially stacked. The insulation layer 320 has a stair-shaped or stepped structure at the word line region 900.

Referring to FIGS. 3E, 4E and 5E, a second conductive layer 330 is formed on the insulation layer 320. The second conductive layer 330 composes a control gate, and for example, can be formed by depositing a polysilicon using a chemical vapor deposition method. The second conductive layer 330 is formed on an entire surface of the substrate 110 having the word line region 900 and the sense line region 800. Since the insulation layer 320 is stepped at the word line region 900, the second conductive layer 330 is also formed to be stepped.

Referring to FIGS. 3F, 4F and 5F, word lines 400 and sense lines 600 are formed by a photolithography process and an etching process. As illustrated in FIG. 3F, each of the sense lines 600 formed at the active region 130 has the first width W₁. The word line 400 and the sense line 600 can be formed by a self-alignment etching process. Each of the word line 400 includes the select gate 300 having the floating gate 311 comprised of the first conductive layer, the gate interlayer dielectric layer 321 composed of the ONO layer, and the control gate 331 composed of the second conductive layer, which are sequentially stacked. The floating gate 311 and the control gate 331 of the select gate 300 are connected to each other, for example, by a butting contact at a predetermined region. Each of the sense lines 600 includes the memory gate 500 having the floating gate 311 composed of the first conductive layer, the gate interlayer dielectric layer 321 composed of the ONO layer, and the control gate 331 composed of the second conductive layer, which are sequentially stacked. The tunnel oxide layer 150 is located under the floating gate 311 of the memory gate 500.

As illustrated in FIG. 4F, the word line 400 formed over the device isolation layer 120 has a structure where the floating gate 311 comprised of the first conductive layer, the gate interlayer dielectric layer 321 comprised of the ONO layer, and the control gate 331 comprised of the second conductive layer are sequentially stacked. The sense line 600 formed over the device isolation layer 120 has a structure where the gate interlayer dielectric layer 321 comprised of the ONO layer and the control gate 331 comprised of the second conductive layer are sequentially stacked. The sense line 600 is formed to have the second width W₂ that is identical to the first width W₁. That is, the sense line 600 is formed to be a straight form in one direction (for example, in a Y direction of FIG. 2A). Especially, since the floating gate isolation region 170 extends to both left and right sides of the active region 140 and are enlarged to a part of a word line region (reference number 900 in FIG. 4D), there is a greatly reduced possibility that a misalignment occurs when an etching process, such as a self-alignment etching process, is performed for forming the sense line 600. Furthermore, in the word line 400, the gate interlayer dielectric layer 321 has a stepped structure, such as a stair shape, by covering an upper surface 311a and a side surface 311b of the floating gate 311, and the control gate 331 formed on the gate interlayer dielectric layer 321 has a “ [symbol] ” shaped structure or a “ [symbol] ” shaped structure.

After the memory gate 500 and the select gate 300 are formed, a photolithography process and an ion-implantation process are performed to form the first junction 140, the second junction 200, and the third junction 190. Particularly, first photolithography and ion-implantation processes are performed to form a high-voltage low-concentration N⁻-type doped region 200b. The high-concentration N⁺-type doped region 200a and the high-voltage low-concentration N⁻-type doped region 200b comprise the second junction 200, which can be named as the floating junction. Then, second photolithography and ion-implantation processes are performed to form a high-concentration N⁺-type junction 140, which can be named as the common source, at the active region 130 between the memory gates 500, and to form a high-concentration N⁺-type junction 190, which can be named as the drain, at a side of the select gate 300.

Referring again to FIG. 4F, when an etching process is performed to form the word line 400 and the sense line 600, a loss occurs at the active region 130 of the substrate 110. The first junction 140 formed at the active region 130 is the common source and can be used as a current path in read operation. Then, the first junction 140 can be formed using high-concentration ion-implantation process to form a high-concentration N⁺-type junction.

Accordingly, the present invention provides an EEPROM device and a method of forming the same, wherein an isolation region for a floating gate isolation extends to both left and right sides of a common source and to a part of a word line. Therefore, it is possible to increase a misalignment process margin between the isolation region and a sense line, thereby resulting in an improved yield. Furthermore, a sense line can be formed to have a straight structure to enlarge an area of a gate interlayer dielectric layer of a memory gate, which can be an ONO layer, and to improve program/erase effects. Consequently, it is possible to embody an EEPROM device having highly improved electrical characteristics.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. An EEPROM device comprising:
a substrate having a first junction extending in a first direction;
word lines extending in the first direction, the word lines being arranged at both sides of the first junction, and each having a select gate comprising a first floating gate, a first control gate, and a first gate interlayer dielectric layer interposed between the first floating gate and the first control gate, wherein the first gate interlayer dielectric layer and the first control gate have stepped shapes; and
sense lines extending in the first direction, the sense lines being arranged between the first junction and the word lines, and each sense line having a memory gate comprising a second floating gate, a second control gate and a second gate interlayer dielectric layer interposed between the second floating gate and the second control gate, wherein the second floating gate is discontinuous in the first direction.

2. The EEPROM device of claim 1, wherein the first floating gate and the second floating gate comprise identical first conductive layers, the first gate interlayer dielectric layer and the second gate interlayer dielectric layer comprise identical insulators, and the first control gate and the second control gate comprise identical second conductive layers.

3. The EEPROM device of claim 1, further comprising a second junction comprising a first impurity doped region and a second impurity doped region under the sense line, wherein one of the first and second impurity doped regions comprises an impurity concentration that is higher than the other.

4. The EEPROM device of claim 3, further comprising a tunnel oxide layer contacting the second junction and defining a path configured to enable an electron to be tunneled into and from the second floating gate.

5. The EEPROM device of claim 3, further comprising a third junction electrically connected to a bit-line contact on the substrate under a side of the word line.

6. The EEPROM device of claim 1, wherein the first gate interlayer dielectric layer covers upper and side surfaces of the first floating gate and has a stair-type shape structure, and the first control gate covers upper and side surfaces of the first gate interlayer dielectric layer to be a square-type structure.

7. An EEPROM device comprising:
a substrate having a common source extending in a first direction;
sense lines extending in the first direction on the substrate, the sense lines being arranged at both sides of the common source, and each having a floating gate, a first gate interlayer dielectric layer, and a first control gate sequentially stacked;
word lines extending in the first direction on the substrate, each having a second floating gate, a second gate interlayer dielectric layer, and a second control gate sequentially stacked; and
a floating gate isolation region extending from the common source in a second direction crossed over the first direction, the floating gate isolation region being defined as a region where an entire portion of the first floating gate and a portion of the second floating gate are removed to discontinuously electrically isolate the first floating gate, and to make the second gate interlayer dielectric layer and the second control gate step-shaped.

8. The EEPROM device of claim 7, wherein the second gate interlayer dielectric layer has a stair-type shape and the second control, gate has a square-type shape.

9. The EEPROM device of claim 7, further comprising a tunnel oxide layer and a floating junction which are electrically connected to the first floating gate under the sense line.

10. The EEPROM device of claim 7, further comprising a drain electrically connected to a bit line contact at the substrate under a side of the word line.

11. A method of forming an EEPROM device, comprising:
preparing a substrate comprising a sense line region and a word line region;
forming a gate oxide layer on the substrate;
forming a tunnel oxide layer at the sense line region;
forming a first conductive layer on the substrate, the first conductive layer crossing over the sense line region to extend to a part of the word line region and defining a floating gate isolation region;
forming an insulation layer and a second conductive layer on the substrate;
patterning the second conductive layer, the insulation layer, and the first conductive layer to form a sense line at the sense line region having a floating gate electrically isolated by the floating gate isolation region and to form a word line at the word line region, wherein the sense line formed at the floating gate isolation region has a structure where the insulation layer and the second conductive layer are evenly stacked on the substrate, and wherein the word line formed at the floating gate isolation region has a structure where the insulation layer and the second conductive layer are unevenly stacked on the first conductive layer; and
forming a first junction, a second junction and a third junction on the substrate.

12. The method of claim 11, wherein the forming the first conductive layer defining the floating gate isolation region comprises:
forming a conductor on the substrate; and
patterning the conductor to remove the conductor formed at the sense line region and a part of the conductor formed at the word line region.

13. The method of claim 11, wherein the substrate comprises an active region between the sense lines regions, and the floating gate isolation region crosses over the active region.

14. The method of claim 11, wherein forming the first through third junctions comprises:
forming the first junction on the substrate between the sense lines;
forming the second junction comprising a first impurity doped region and a second impurity doped region, including forming the first impurity doped region on the substrate under the sense line, and forming the second impurity doped region connected to the first impurity doped region on the substrate between the sense line and the word line; and
forming the third junction on the substrate under a side of the word line.

15. The method of claim 14, wherein the formation of the first impurity doped region is performed in a step of the formation of the tunnel oxide layer, and the formation of the second impurity doped region is performed in a step of the formation of the first through third junctions.

16. The method of claim 15, wherein an impurity concentration is higher in the first than in the second impurity doped region.

17. The method of claim 11, wherein forming the structure where the insulation layer and the second conductive layer are unevenly stacked on the first conductive layer comprises:
forming an insulation layer on upper and side surfaces of the first conductive layer to be stair-type shape at the word line region; and
forming the second conductive layer to be square-type shape on the insulation layer.

18. The method of claim 11, wherein the sense line is formed to extend straightly in a direction orthogonal to an extension direction of the floating gate isolation region.

19. A method of forming an EEPROM device, comprising:
providing a substrate having a sense line region and a word line region;
forming a gate oxide layer on the substrate;
forming a tunnel oxide layer having a thinner thickness than the gate oxide layer;
forming a first impurity doped region under the tunnel oxide layer on the sense line region;
forming a first conductive layer on the substrate;
patterning the first conductive layer to form a first conductive pattern exposing an entire part of the substrate of the sense line region but exposing a part of the substrate of the word line region;
forming an insulation layer and a second conductive layer on the substrate;
patterning the second conductive layer, the insulation layer, and the first conductive pattern to form a sense line straightly extending in one direction at the sense line region where an entire surface of the substrate is exposed and a word line at the word line region where a part of the substrate is exposed,
wherein the sense line comprises the insulation layer and the second conductive layer sequentially stacked, and
wherein the word line comprises the first conductive layer, the insulation layer covering upper and side surfaces of the first conductive layer and having a stair-type shape, and the second conductive layer being positioned on the insulation layer and having a square-type shape;
forming a common source on the substrate between the sense lines;
forming a second impurity doped region connected to the first impurity doped region on the substrate between the sense line and the word line to constitute a floating junction comprising the first and second impurity doped regions; and
forming a drain on the substrate under the word line.

20. The method of claim 19, wherein an impurity concentration is higher in the first than in the second impurity doped region.
